(19) United States
(12) Patent Application Publication
(10) Pub. No.: US 2024/0367282 A1
(43) Pub. Date: Nov. 7, 2024

(54) POLISHING METHOD AND POLISHING APPARATUS

(71) Applicant: EBARA CORPORATION, Tokyo (JP)

(72) Inventors: Hisashi SARUWATARI, Tokyo (JP); Kenichi SUZUKI, Tokyo (JP)

(21) Appl. No.: 18/645,662

(22) Filed: Apr. 25, 2024

(30) Foreign Application Priority Data
May 1, 2023 (JP) 2023-075419

(51) Int. Cl. B24B 37/34; B24B 37/005; B24B 37/30

(52) U.S. Cl. CPC B24B 37/345; B24B 37/005; B24B 37/30

(57) ABSTRACT

A polishing method is disclosed, in which a substrate can be released from a substrate holder to pass the substrate to a transfer device without damaging the substrate. The polishing head, which holds the substrate after polishing, is moved above a stage of the transfer device that is in the substrate detection position, and an elastic membrane is inflated until a substrate detection sensor provided in the transfer device detects an approach of the substrate to the stage. After the inflation of the elastic membrane is stopped, the stage is moved from the substrate detection position to a substrate receive position using an elevating device, and then gas is injected from a injection nozzle to a boundary between the substrate and the elastic membrane adhered to the substrate, causing the substrate to be released from a substrate holding surface of the elastic membrane.

### CROSS REFERENCE TO RELATED APPLICATION

This document claims priority to Japanese Patent Application No. 2023-075419 filed May 1, 2023, the entire contents of which are hereby incorporated by reference.

### BACKGROUND

In a manufacturing process of the semiconductor devices, a planarization technique of a surface of the semiconductor device is becoming more important. The most important technique in this planarization technique is chemical mechanical polishing. This chemical mechanical polishing (which will be hereinafter called CMP) is a process of polishing a substrate, such as a wafer, by placing the substrate in sliding contact with a polishing pad while supplying a polishing liquid containing abrasive grains, such as silica (SiO₂), onto the polishing pad.

In a CMP apparatus, when a substrate is peeled off from an elastic membrane in a substrate holder, which is referred to as a polishing head or a top ring, the elastic membrane is inflated by supplying gas having a certain pressure into the elastic membrane. Next, a release gas, such as nitrogen gas, is blown to a boundary between the substrate (e.g., a wafer) adhered to the elastic membrane and the inflated elastic membrane to thereby peel off the substrate from the elastic membrane (see Patent Document 1, for example). The substrate peeled off from the substrate holder is then passed to a stage of a transfer device.

When the substrate is peeled off from the elastic membrane by blowing the release gas to the boundary between the substrate and the inflated elastic membrane, a downward force may be applied to the substrate, and thus the substrate (especially a periphery of the substrate) may be pressed against the stage of the transfer device. As a result, the substrate itself may be damaged, or devices formed on a device surface may be damaged.

### SUMMARY

Accordingly, there are provided a polishing method and a polishing apparatus capable of releasing a substrate from a substrate holder to pass the substrate to a transfer device without damaging the substrate.

Embodiments, which will be described below, relate to a polishing method and a polishing apparatus for polishing a substrate, such as a wafer.

In one embodiment, there is provided a polishing method of a substrate using a polishing head having a substrate holding surface and at least one pressure chamber composed of an elastic membrane, comprising: performing polishing of the substrate by pressing the substrate against a polishing pad on a polishing table using pressure of fluid supplied to the pressure chamber while causing the substrate and the polishing pad to be moved relative to each other; moving the polishing head, which has held the polished substrate, above a stage of a transfer device that is in a substrate detection position; inflating the elastic membrane until a substrate detection sensor provided in the transfer device detects an approach of the substrate to the stage; moving the stage from the substrate detection position to a substrate receive position using an elevating device after the inflation of the elastic membrane is stopped; releasing the substrate from the substrate holding surface by injecting gas from an injection nozzle to a boundary between the substrate and the elastic membrane adhered to the substrate; and receiving the released substrate to the stage.

In one embodiment, the released substrate is received to the stage supported through an elastic member to a support stage.

In one embodiment, inflating the elastic membrane is performed so that the substrate is not in contact with the stage.

In one embodiment, the substrate detection sensor is an optical sensor having a light emitter and a light receiver that receives light emitted from the light emitter, and inflating the elastic membrane is performed until the light emitted from the light emitter toward the light receiver is intercepted by a back surface of the substrate.

In one embodiment, there is provided a polishing apparatus, comprising: a polishing table for supporting a polishing pad; a polishing head which has a substrate holding surface and a pressure chamber composed of an elastic membrane, and is configured to hold the substrate by use of the substrate holding surface and press the substrate against the polishing pad by use of a pressure of fluid supplied to the pressure chamber; a transfer device configured to receive the polished substrate from the polishing head; and a controller configured to control operations of at least the polishing head and the transfer device, wherein the controller causes the polishing head, which has held the polished substrate, to be moved above a stage of the transfer device that is in a substrate detection position; causes the elastic membrane to be inflated until a substrate detection sensor provided in the transfer device detects an approach of the substrate to the stage; causes the stage to be moved from the substrate detection position to a substrate receive position using an elevating device after the inflation of the elastic membrane is stopped; causes the substrate to be released from the substrate holding surface by injecting gas from an injection nozzle to a boundary between the substrate and the elastic membrane adhered to the substrate; and causes the released substrate to be received to the stage.

In one embodiment, the transfer device includes a support stage configured to support the stage through an elastic member.

In one embodiment, the controller causes the elastic membrane to be inflated so that the substrate is not in contact with the stage.

In one embodiment, the substrate detection sensor is an optical sensor having a light emitter and a light receiver that receives light emitted from the light emitter, and the controller causes the elastic membrane to be inflated until the light emitted from the light emitter toward the light receiver is intercepted by a back surface of the substrate.

The stage is moved from the substrate detection position to the substrate receive position before gas is injected from the injection nozzles to the boundary between the substrate and the elastic membrane adhered to the substrate. Therefore, the substrate is prevented from being pressed against the stage even if a downward force is applied to the substrate, and the substrate is not damaged by contact of the substrate with the stage.

### BRIEF DESCRIPTION OF THE DRAWINGS

FIG. 1 is a diagonal view schematically showing a polishing apparatus according to one embodiment;

FIG. 2 is a top view schematically showing an example of arrangement of injection nozzles;

FIG. 3 is a cross-sectional view schematically showing a polishing head shown in FIG. 1;

FIG. 4 is a side view schematically showing a transfer device according to one embodiment;

FIG. 5 is a top view showing a stage of the transfer device shown in FIG. 4.

FIG. 6 is a side view schematically showing a substrate detection sensor according to another embodiment;

FIG. 7 is a flowchart illustrating a transfer process according to one embodiment; and

FIGS. 8A to 8E are schematic views each showing a state of the transfer process.

### DESCRIPTION OF EMBODIMENTS

Hereinafter, embodiments will be described with reference to the drawings.

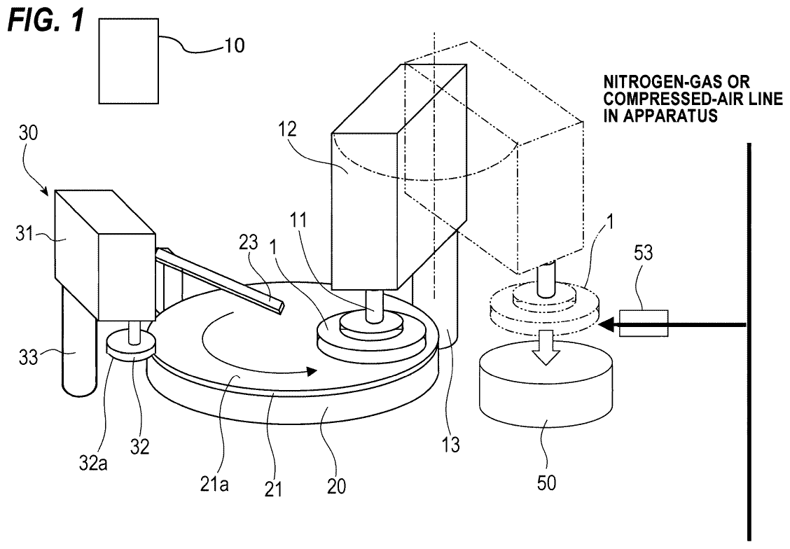

FIG. 1 is a diagonal view schematically showing a polishing apparatus according to one embodiment. The polishing apparatus shown in FIG. 1 has a polishing table 20, and a polishing head (i.e., substrate holder) 1 for holding a wafer W, which is an example of a substrate, and pressing the wafer W against a polishing pad located on the polishing table 20. The polishing head 1 may be referred to as a “top ring”.

The polishing table 20 is coupled to a table motor (not shown) through a table shaft, and is configured to be rotatable around the table shaft. The table motor is located below the polishing table 20. The polishing pad 21 is attached to an upper surface of the polishing table 20. The polishing pad 21 has an upper surface, which provides a polishing surface 21a for polishing the wafer W. A polishing-liquid supply nozzle 23 is provided above the polishing table 20, so that a polishing liquid (e.g., slurry) is supplied from this polishing-liquid supply nozzle 23 onto the polishing pad 21 mounted to the polishing table 20.

The polishing head 1 is coupled to a head shaft 11, and the head shaft 11 is movable vertically relative to a head arm 12. A vertical movement and positioning of the polishing head 1 in its entirety relative to the head arm 12 are achieved by the vertical movement of the polishing head shaft 11. The head shaft 11 can be rotated by driving of a shaft rotation motor (not shown). The rotation of the head shaft 11 enables the polishing head 1 to rotate around the head shaft 11.

The polishing head 1 is configured to be able to hold the wafer W on its lower surface. The head arm 12 is configured to be pivotable about an arm shaft 13, and thus, the polishing head 1, which holds the substrate W on its lower surface, is movable between a substrate transfer position and a position above the polishing table 20 by the pivotable movement of the head arm 12. The polishing head 1 holds the substrate W on its lower surface, and presses the substrate W against the surface (polishing surface) of the polishing pad 21. At this time, while the polishing table 20 and the polishing head 1 are respectively rotated, a polishing liquid (slurry) is supplied onto the polishing pad 21 from the polishing-liquid supply nozzle 23 provided above the polishing table 20. The polishing liquid containing abrasive particles (e.g., silica (SiO₂) or ceria (CeO₂)) is used. In this manner, while the polishing liquid is supplied onto the polishing pad 21, the substrate W is pressed against the polishing pad 21, and the substrate W and the polishing pad 21 are moved relative to each other to polish a film (e.g., insulating film or metal film) on the surface of the wafer W.

As shown in FIG. 1, the polishing apparatus has a dressing unit 30 for dressing the polishing pad 21. The dressing unit 30 includes a dresser head 31, a dresser 32 which is rotatably attached to one end of the dresser head 31, and a swing shaft 33 which is coupled to the other end of the dresser head 31. A lower part of the dresser 32 comprises a dressing member 22a, which has a circular dressing surface. Hard particles are fixed to the dressing surface. Examples of the hard particles may include diamond particles, ceramic particles and the like. A motor (not shown) is provided in the dresser head 31, and the dresser 32 is rotated by the motor.

As shown in FIG. 1, a transfer device 50 is placed at a side of the polishing table 20. The transfer device 50 serves as a device for transferring the polished wafer W to another apparatus (e.g., a cleaning apparatus for the wafer W). At least one injection nozzle 53, which is used to inject a release gas as described below, is provided radially outwardly of the transfer device 50.

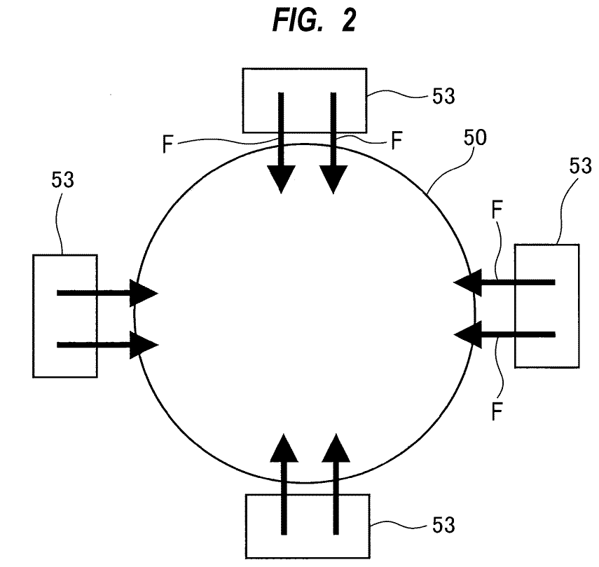

The injection nozzles 53 are coupled to a gas line (e.g., a nitrogen-gas line or a compressed-air line) disposed in the polishing apparatus, and a gas, such as nitrogen gas or compressed air, is injected from the injection nozzles 53 as a release gas. Type of the release gas is freely selectable, but inert gas, such as nitrogen gas, is preferably used as the release gas. As shown in FIG. 2, a plurality of (four in FIG. 2) injection nozzles 53 are provided at intervals in a circumferential direction, for example, so as to surround the transfer device 50. In the example shown in FIG. 2, each injection nozzle 53 has two injection ports for injecting the release gas.

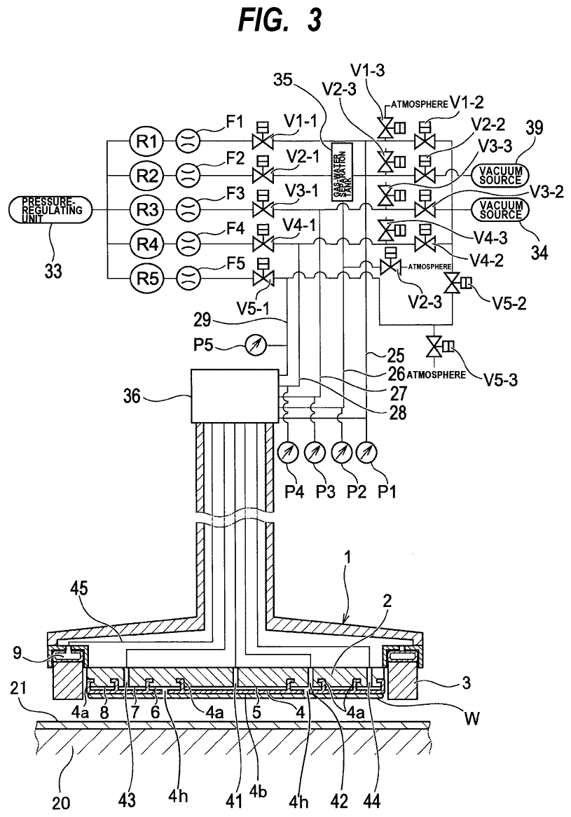

FIG. 3 is a cross-sectional view schematically showing the polishing head shown in FIG. 1. In FIG. 3, only the major components of the polishing head 1 are illustrated. As shown in FIG. 3, the polishing head 1 is essentially composed of an elastic membrane (membrane) 4 for pressing the wafer W against the polishing pad 21, a head body (also referred to as a carrier) 2 for holding the membrane 4, and a retainer ring 3 which directly presses the polishing pad 21. The head body 2 is formed of an approximately disk-shaped member, and the retainer ring 3 is attached to a periphery of the head body 2. The head body 2 is made of resin, such as engineering plastic (e.g., PEEK). The elastic membrane 4, which is configured to come in contact with a back surface of the wafer W, is attached to a lower surface of the head body 2. The elastic membrane 4 is made of a rubber material with high strength and durability, such as ethylene-propylene rubber (EPDM), polyurethane rubber, and silicone rubber.

The elastic membrane 4 has a plurality of partition walls 4a which are concentrically arranged. These partition walls 4a make a plurality of pressure chambers, i.e., a circular central chamber 5, an annular ripple chamber 6, an annular outer chamber 7, and an annular edge chamber 8, between an upper surface of the elastic membrane 4 and a lower surface of the head body 2. The central chamber 5 is formed in a center portion of the head body 2, and the ripple chamber 6, the outer chamber 7, and the edge chamber 8 are formed in a concentric manner, sequentially from center to outer circumference.

The wafer W is held on a substrate holding surface 4b of the elastic membrane 4. The elastic membrane 4 has a plurality of holes 4h for wafer suction located at positions corresponding to the position of the ripple chamber 6. While the holes 4h are located in the corresponding position of the ripple chamber 6 in this embodiment, the holes 4h may be located at positions of other pressure chamber. A passage 41 communicating with the central chamber 5, a passage 42 communicating with the ripple chamber 6, a passage 43 communicating with the outer chamber 7, and a passage 44 communicating with the edge chamber 8 are formed in the head body 2. The passage 41, the passage 43, and the passage 44 are coupled via the rotary joint 36 to passages 25, 27, and 28, respectively. These passages 25, 27, and 28 are coupled to a pressure-regulating unit 30 via respective valves V1-1, V3-1, and V4-1, and respective pressure regulators R1, R3, and R4. The passages 25, 27, and 28 are coupled to a vacuum source 34 through valves V1-2, V3-2, and V4-2, respectively, and further communicate with the atmosphere through valves V1-3, V3-3, and V4-3, respectively.

The passage 42, communicating with the ripple chamber 6, is coupled to the passage 26 via the rotary joint 36. The passage 26 is coupled to the pressure-regulating unit 30 via a gas-water separation tank 35, a valve V2-1, and a pressure regulator R2. Further, the passage 26 is coupled to a vacuum source 39 via the gas-water separation tank 35 and a valve V2-2, and further communicates with the atmosphere via a valve V2-3.

An annular retainer-ring pressure chamber 9, which is formed by an elastic membrane, is provided right above the retainer ring 3. This retainer-ring pressure chamber 9 is coupled to a passage 29 via a passage 45 formed in the head body 2 and via the rotary joint 36. The passage 29 is coupled to the pressure regulating unit 33 via a valve V5-1 and a pressure regulator R5. Further, the passage 29 is coupled to the vacuum source 34 via a valve V5-2, and communicates with the atmosphere through a valve V5-3. The pressure regulators R1, R2, R3, R4, and R5 have a pressure regulating function to regulate pressures of fluid (e.g., gas, such as air or nitrogen) supplied from the pressure regulating unit 33 to the central chamber 5, the ripple chamber 6, the outer chamber 7, the edge chamber 8, and the retainer-ring pressure chamber 9, respectively. The pressure regulators R1, R2, R3, R4, and R5 and the valves V1-1 to V1-3, V2-1 to V2-3, V3-1 to V3-3, V4-1 to V4-3, and V5-1 to V5-3 are coupled to a controller (not shown), so that operations thereof are controlled by the controller. Further, pressure sensors P1, P2, P3, P4, and P5, and flow rate sensors F1, F2, F3, F4, and F5 are mounted to the passages 21, 22, 23, 24, and 26, respectively.

The pressures in the central chamber 5, the ripple chamber 6, the outer chamber 7, the edge chamber 8, and the retainer-ring pressure chamber 9 are measured by the presser sensors P1, P2, P3, P4, and P5, respectively. Flow rates of the pressurized fluid supplied to the central chamber 5, the ripple chamber 6, the outer chamber 7, the edge chamber 8, and the retainer-ring pressure chamber 9 are measured by the flow rate sensors F1, F2, F3, F4, and F5, respectively.

In the polishing head 1 configured as shown in FIG. 3, the pressures of fluid supplied to the central chamber 5, the ripple chamber 6, the outer chamber 7, and the edge chamber 8 can be independently controlled by the pressure regulating unit 33 and the pressure regulators R1, R2, R3, R4, and R5. With this structure, forces of pressing the wafer W against the polishing pad 21 can be adjusted at respective local areas of the wafer, and a force of pressing the retainer ring 3 against the polishing pad 21 can be adjusted. Further, when the wafer is released, the pressurized fluids can be supplied to the pressure chambers 5, 6, 7, and 8 to inflate the elastic membrane 4.

Next, a sequence of polishing process in the polishing apparatus described above will be described.

The polishing head 1 receives the wafer W at the substrate transfer position and holds the wafer W thereon via the vacuum suction. Holding of the wafer W under the vacuum suction is achieved by producing a vacuum in the holes 4h that are in fluid communication with the vacuum source 39. The polishing head 1 which holds the wafer W is lowered to a preset polishing position of the polishing head 1. At this time, the polishing table 20 and the polishing head 1 are being rotated about their own axes. In this state, the elastic membrane 4, which is provided at the back side of the wafer W, is inflated to bring the surface of the wafer W into contact with the polishing surface 21a of the polishing pad 21. The polishing pad 21 and the wafer W are moved relative to each other, thereby polishing the surface of the wafer W.

After the polishing process of the wafer W on the polishing pad 21 is completed, the wafer W is held by the polishing head 1 with vacuum suction. Then, a transfer process is performed, in which the polishing head 1 is elevated, the head arm 12 is swung to move the polishing head 1 above the transfer device 50, and the wafer W is detached (i.e., released) to the transfer device 50.

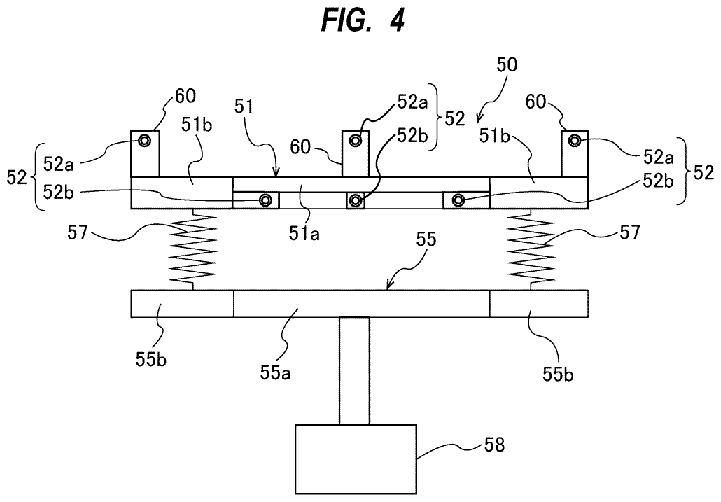

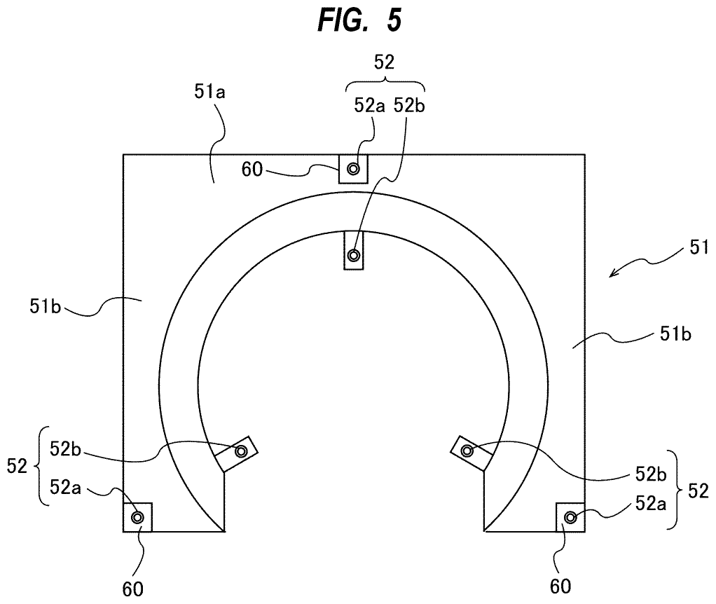

FIG. 4 is a side view schematically showing a transfer device according to one embodiment, and FIG. 5 is a top view showing a stage of the transfer device shown in FIG. 4. The transfer device 50 shown in FIG. 4 has a stage 51 configured to receive the wafer W released from the polishing head 1, at least one (three in the example shown in FIG. 5) substrate detection sensor 52 configured to be able to detect an approach of the wafer W to the stage 51, a support stage 55 configured to support the stage 51, a plurality of elastic members 57 for coupling the stage 51 to the support stage 55, and an elevating device 58 coupled to the support stage 55. In one embodiment, the elastic members 57 and the support stage 55 may be omitted. In this case, the elevating device 58 is coupled to the stage 51.

The support stage 55 is disposed below the stage 51. One end of the elastic member 57 is secured to an upper surface of the support stage 55, and the other end of the elastic member 57 is secured to a lower surface of the stage 51. Thus, the elastic members 57 are arranged so as to be sandwiched between the support stage 55 and the stage 51. Although two elastic members 57 are illustrated in FIG. 4, in actuality, two more elastic members exist behind the two illustrated elastic members 57 on the far side of the paper. In other words, in this embodiment, the transfer device 50 has four elastic members 57, and the stage 51 is supported by the support stage 55 through the four elastic members 57.

As shown in FIG. 5, the stage 51 has an approximate U-shaped form when viewed in a horizontal plane. More specifically, the stage 51 is composed of a base 51a and two arms 51b, 51b extending from both ends of the base 51a. The arms 51b, 51b extend horizontally from the base 51a and parallel to each other. The stage 51 has a recess for receiving the wafer W released from the polishing head 1, this recess being formed at an inner edge of the base 51a and the arms 51b, 51b. The recess is formed, for example, corresponding to an external shape of the wafer W, and in the inner edge of the stage 51 having the approximately U-shaped form.

Although the transfer device 50 has three substrate detection sensors 52 in this embodiment, the number of substrate detection sensors 52 can be freely determined. However, when the transfer device 50 has three (or more) substrate detection sensors 52, monitoring whether or not all of the substrate detection sensors 52 detect the approach of the wafer W to the stage 51 enables detection of whether or not a position failure and/or a posture failure of the wafer W with respect to the stage 51 has occurred.

In this embodiment, the support stage 55 has almost the same shape as the stage 51. Specifically, the support stage 55 has an approximate U-shaped form, which is composed of a base 55a and two arms 55b, 55b extending horizontally from both ends of the base 55a and parallel to each other.

Each of the substrate detection sensors 52 shown in FIG. 4 is a light detection sensor composed of a light emitter 52a and a light receiver 52b, and is configured to detect the approach of the wafer W to the stage 51 by interception of light emitted from the light emitter 52a to the light receiver 52b. Each light emitter 52a is mounted to a tip end (upper end) of a sensor base 60 mounted to an upper surface of the stage 51, and a light receiver 52b is mounted in the recess formed in the inner edge of the stage 51 to receive the wafer W. The light emitter 52a emits light diagonally downward to the light receiver 52b. With this configuration, the light emitted from the light emitter 52a hits only the back surface of the wafer W on which no device is formed, thereby preventing the devices formed on the surface of the wafer W from being damaged by the light from the substrate detection sensor 52.

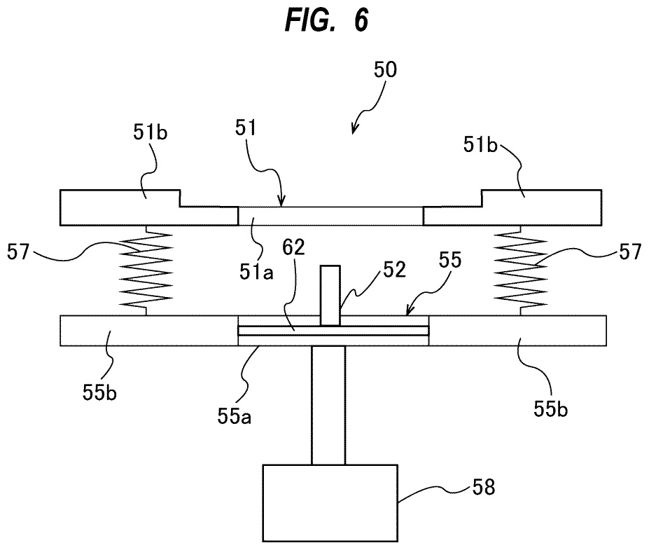

Type and configuration of the substrate detection sensor 52 is freely selectable as long as the sensor can detect the approach of the wafer W to the stage 51 without adversely affecting the devices formed on the surface of the wafer W. FIG. 6 is a side view schematically showing the substrate detection sensor according to another embodiment. The substrate detection sensor 52 shown in FIG. 6 is a distance-measurement sensor which is mounted to a sensor base 62 secured to the two arms 55b, 55b of the support stage 55. Examples of distance-measurement sensor may include an ultrasonic sensor. The substrate detection sensor 52, which is an ultrasonic sensor, can measure a distance between the sensor base 62 and the wafer W by emitting ultrasonic waves toward the surface of the wafer W and then receiving the reflected waves. With this configuration also, the substrate detection sensor 52 can indirectly detect the approach of the wafer W to the stage 51. Although not shown, the transfer device 50 may have both the substrate detection sensor 52 shown in FIG. 6 and the substrate detection sensor 52 shown in FIG. 4.

The elevating device 58 shown in FIG. 4 serves as a device for moving the support stage 55 in a vertical direction. The elevating device 58 may be, for example, a linear air-cylinder mechanism which is composed of a cylinder and a piston capable of moving up and down inside the cylinder by gas supplied to the cylinder, or may be a motor-driven mechanism using a ball-screw. When the elevating device 58 is set in motion, the support stage 55 and together the stage 51 coupled to the support stage 55 through the elastic members 57 are moved up and down. When the elastic members 57 and the support stage 55 are omitted, the elevating device 58 is directly connected to the stage 51.

In this embodiment, each of the elastic members 57 is a coil spring extending from the upper surface of the support stage 55 to the lower surface of the stage 51. In one embodiment, each of the elastic members 57 may be a plate spring.

Next, the transfer process of the wafer W will be described.

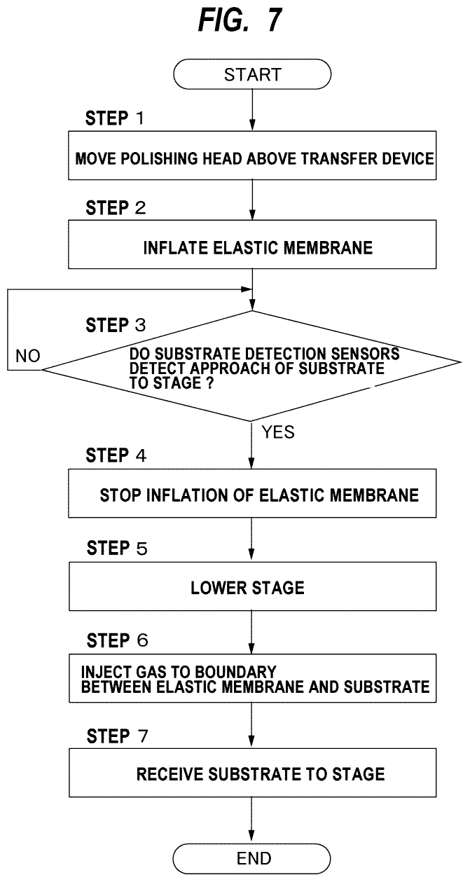

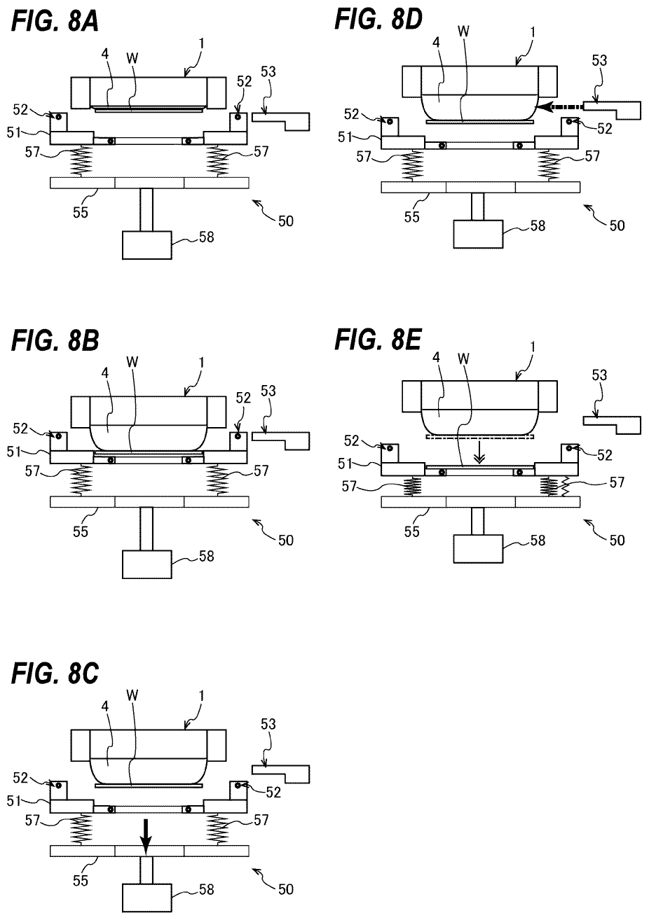

FIG. 7 is a flowchart illustrating a transfer process according to one embodiment. FIGS. 8A to 8E are schematic views each showing a state of the transfer process. Although only one injection nozzle 53 is illustrated in FIGS. 8A to 8E, the number of injection nozzles 53 can be freely determined as described above. Further, as shown in FIG. 1, the polishing apparatus includes a controller 10 that controls operations of the polishing apparatus in its entirety, including not only the transfer process of the wafer W, which will be described below, but also the polishing process of the wafer W and the dressing process of the polishing pad 21, which are described above.

As shown in FIG. 8A, the controller 10 causes the polished wafer W to be vacuum-attached to the elastic membrane 4 of the polishing head 1, and in this state, the arm shaft 13 (see FIG. 1) to be pivoted, thereby moving the polishing head 1 above the transfer device 50 (step 1 in FIG. 7). At this time, the controller 10 operates the elevating device 58 of the transfer device 50 to adjust the vertical position of the stage 51, such that the distance between the polishing head 1 and the stage 51 of the transfer device 50 becomes a predetermined distance.

Next, the controller 10 causes the fluid having a predetermined pressure to be supplied into the pressure chambers 5, 6, 7, and 8 of the polishing head 1, thereby inflating the elastic membrane 4 (step 2 in FIG. 7). As the elastic membrane 4 is inflated, the wafer W attached to the elastic membrane 4 of the polishing head 1 gradually approaches the stage 51. The controller 10 monitors whether or not the wafer W has approached the stage 51 using the substrate detection sensor 52 (step 3 in FIG. 7). Then, as shown in FIG. 8B, when the substrate detection sensor 52 detects the proximity of the wafer W to the stage 51 (“YES” in step 3 of FIG. 7), the controller 10 stops the supply of fluid to the pressure chambers 5, 6, 7, and 8 of the polishing head 1 to stop the expansion of the elastic membrane 4 (step 4 of FIG. 7). During this process, the elastic membrane 4 is not depressurized. In other words, even after the supply of fluid to the pressure chambers 5, 6, 7, and 8 is stopped, the inflated elastic membrane 4 maintains the shape thereof. In consideration of the effect on the devices formed on the surface of the wafer W when the elastic membrane 4 is being inflated, the wafer W preferably does not come into contact with the stage 51.

The vertical position of the stage 51 to be moved in step1, relative to the polishing head 1 is determined in advance in accordance with an amount of inflation in the elastic membrane 4 that enables the release gas to stably peel off the wafer W from the elastic membrane 4. If the distance between the wafer W and the polishing head 1 is too far when the substrate detection sensors 52 detect that the wafer W has approached the stage 51, posture of the wafer W attached to the inflated elastic membrane 4 may be at an angle with respect to the polishing head 1. Accordingly, the vertical position of the stage 51 relative to the polishing head 1 is set properly. The vertical position of the stage 51 relative to the polishing head 1 is determined in advance, for example, by experiments and/or simulations. In this specification, the vertical position of the stage 51 relative to the polishing head 1, which is moved in step 1, is referred to as the “substrate detection position”. The substrate detection position is stored in the controller 10 in advance, and may be changed according to types of the wafer W and the elastic membrane 4.

As shown in FIG. 8C, when the approach of the wafer W to the stage 51 is detected, the controller 10 causes the stage 51 to be lowered (moved) from the substrate detection position and brought away from the polishing head 1 (step 5 in FIG. 7) using the elevating device 58. A distance at which the stage 51 is lowered from the substrate detection position in step 5 is determined in advance as a size that prevents the wafer W (especially the periphery of the wafer W in contact with the stage 51) from being pressed against the stage 51 and damaged while the release gas causes the wafer W to be subjected to a downward force, peeling off the wafer W from the elastic membrane 4. In this specification, the position of the stage 51 lowered from the substrate detection position in step 5 is referred to as the “substrate receive position”. This substrate receive position is also determined in advance by experiments and/or simulations.

As shown in FIG. 8D, after the stage 51 is lowered to the substrate receive position, the controller 10 causes the release gas to be injected from the injection nozzles 53 toward the boundary between the wafer W and the elastic membrane 4 adhered to the wafer W (step 6 in FIG. 7). The injection nozzles 53 are arranged such that the release gas injected from the injection nozzles 53 does not hit the surface of the wafer W, but properly hits the boundary between the wafer W and the elastic membrane 4 adhered to the wafer W. The injection nozzles 53 are secured, for example, to walls around the transfer device 50. Further, when the substrate detection sensors 52 provided in the stage 51 detect that the wafer W has approached the stage 51, the supply of fluid to the elastic membrane 4 is stopped. As a result, the elastic membrane 4 inflating prevents the wafer W from being excessively pressed against the stage 51, so that the devices formed on the surface of the wafer W are not damaged by the contact with the stage 51. Moreover, after the substrate detection sensors 52 provided in the stage 51 detect that the wafer W has approached the stage 51, the release gas is injected from the injection nozzles 53. Therefore, occurrence of damages or defects in the devices can be prevented, which are caused by applying the injection of release gas while the elastic membrane 4 is not fully inflated, thereby hitting the release gas to the surface of the wafer W and drying the wafer W. In addition, when the approach of the wafer W to the stage 51 is detected, the stage 51 is lowered (moved) from the substrate detection position to the substrate receive position. As a result, the wafer W is prevented from being continuously pressed against the stage 51 by the elastic membrane 4, and thus the devices formed on the surface of the wafer W are not damaged by contact with the stage 51.

As shown in FIG. 8E, the release gas injected from the injection nozzles 53 causes the wafer W to be peeled off from the elastic membrane 4 of the polishing head 1 and to fall onto the stage 51. The controller 10 monitors whether or not receipt of the substrate is completed using the substrate detection sensors 52 mounted to the stage 51 that has been moved to the substrate receive position. Specifically, when the substrate detection sensors 52 detect the approach of the wafer W to the stage 51 after the stage 51 has been moved to the substrate receive position, the controller 10 determines that the wafer W has fallen from the polishing head 1 and has been received on the stage 51 (step 7 in FIG. 7). In this manner, the process of receiving the wafer W from the polishing head 1 to the stage 51 of the transport device 50 is performed.

In this embodiment, the stage 51 is coupled to the support stage 55 through the elastic members 57. Therefore, as shown in FIG. 8E, when the wafer W falls onto the stage 51, the elastic members 57 are retracted, and thus impact generated on the wafer W is greatly reduced. As a result, damage to the devices formed on the surface of wafer W is prevented.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A polishing method of a substrate using a polishing head having a substrate holding surface and at least one pressure chamber composed of an elastic membrane, comprising:
performing polishing of the substrate by pressing the substrate against a polishing pad on a polishing table using pressure of fluid supplied to the pressure chamber while causing the substrate and the polishing pad to be moved relative to each other;
moving the polishing head, which has held the polished substrate, above a stage of a transfer device that is in a substrate detection position;
inflating the elastic membrane until a substrate detection sensor provided in the transfer device detects an approach of the substrate to the stage;
moving the stage from the substrate detection position to a substrate receive position using an elevating device after the inflation of the elastic membrane is stopped;
releasing the substrate from the substrate holding surface by injecting gas from an injection nozzle to a boundary between the substrate and the elastic membrane adhered to the substrate; and
receiving the released substrate to the stage.

2. The polishing method according to claim 1, wherein the released substrate is received to the stage supported through an elastic member to a support stage.

3. The polishing method according to claim 1, wherein inflating the elastic membrane is performed so that the substrate is not in contact with the stage.

4. The polishing method according to claim 1, wherein the substrate detection sensor is an optical sensor having a light emitter and a light receiver that receives light emitted from the light emitter, and
inflating the elastic membrane is performed until the light emitted from the light emitter toward the light receiver is intercepted by a back surface of the substrate.

5. A polishing apparatus, comprising:
a polishing table for supporting a polishing pad;
a polishing head which has a substrate holding surface and a pressure chamber composed of an elastic membrane, and is configured to hold the substrate by use of the substrate holding surface and press the substrate against the polishing pad by use of a pressure of fluid supplied to the pressure chamber;
a transfer device configured to receive the polished substrate from the polishing head; and
a controller configured to control operations of at least the polishing head and the transfer device,
wherein the controller
causes the polishing head, which has held the polished substrate, to be moved above a stage of the transfer device that is in a substrate detection position;
causes the elastic membrane to be inflated until a substrate detection sensor provided in the transfer device detects an approach of the substrate to the stage;
causes the stage to be moved from the substrate detection position to a substrate receive position using an elevating device after the inflation of the elastic membrane is stopped;
causes the substrate to be released from the substrate holding surface by injecting gas from an injection nozzle to a boundary between the substrate and the elastic membrane adhered to the substrate; and
causes the released substrate to be received to the stage.

6. The polishing apparatus according to claim 5, wherein the transfer device includes a support stage configured to support the stage through an elastic member.

7. The polishing apparatus according to claim 5, wherein the controller causes the elastic membrane to be inflated so that the substrate is not in contact with the stage.

8. The polishing apparatus according to claim 5, wherein the substrate detection sensor is an optical sensor having a light emitter and a light receiver that receives light emitted from the light emitter, and
the controller causes the elastic membrane to be inflated until the light emitted from the light emitter toward the light receiver is intercepted by a back surface of the substrate.
